(19) United States
(12) Patent Application Publication
(10) Pub. No.: US 2026/0259264 A1
(43) Pub. Date: Sep. 3, 2026

(54) SYSTEM AND METHOD FOR SIGNAL TIMING ERROR CORRECTION

(71) Applicant: Rohde & Schwarz GmbH & Co. KG, Munich (DE)

(72) Inventors: Matthias RUENGELER, Kirchheim (DE); Brigitte ENDRES, Pliening (DE); Christian WICKE, Munich (DE)

(21) Appl. No.: 19/377,816

(22) Filed: Nov. 3, 2025

Related U.S. Application Data
(63) Continuation-in-part of application No. 19/067,283, filed on Feb. 28, 2025.

(51) Int. Cl. G01R 31/3193

(52) U.S. Cl. CPC G01R 31/31937; G01R 31/31932

(57) ABSTRACT

The present disclosure relates to a system for signal timing error correction. The system comprises a receiver configured to receive a repetitive challenge signal from a device-under-test, DUT; and a signal generator; wherein, in response to the reception of the challenge signal, the receiver is configured to trigger the signal generator to generate a response signal; and wherein the receiver is configured to receive the response signal. The system further comprises a controller configured to calculate a response time between the reception of the challenge signal and the reception of the response signal by the receiver; wherein the controller is configured to compare the calculated response time to a target response time; wherein the signal generator is configured to generate a repetitive reply signal to the challenge signal and to forward the reply signal to the DUT; and wherein the signal generator is configured to apply a time offset to said reply signal based on the comparison of the calculated response time to the target response time.

### RELATED APPLICATION

This is a continuation-in-part application claiming the benefit of priority to U.S. application Ser. No. 19/067,283, “SYSTEM AND METHOD FOR SIGNAL TIMING ERROR CORRECTION,” filed Feb. 29, 2025, the contents of which is incorporated by reference herein in its entirety.

### TECHNICAL FIELD

The present disclosure relates to systems and methods for signal timing error correction between a received signal from a DUT and a reply signal, for example, in the field of radar target simulation.

### BACKGROUND ART

In certain radar applications, such as automotive radars, a challenge packet from a radar sensor is immediately reflected by a radar target within nanoseconds, e.g., after already 30 cm in case of a very close target.

A radar target simulator with a deterministic, user selected impulse response allows simulating radar targets at different distances from a radar DUT. However, generating an immediate response to the incoming packet, e.g. after only 1 ns when simulating very short distances, is difficult. The internal ADCs and DACs of most radar target simulators are not designed for low latency and have internal delays of more than a few ns. This issue could be mitigated by a digitally switchable analog delay line which can respond after a new nanoseconds. However, the impulse response of such a delay line is typically not freely configurable. Often, only one delay path and one reflection can be configured.

A further issue of many radar target simulators is the trigger accuracy of their analyzer which receives the radar signal from the DUT and controls the generation of a reply (i.e., echo) signal. The triggering of the reply signal has both deterministic and random timing errors which can lead to unwanted time shifts in the reply signal and can make it difficult to accurately simulate a certain target distance.

Accordingly, there is a need to provide a method and a system for signal timing error correction which overcome the above mentioned disadvantages and limitations. In particular, there is a need to reduce a signal timing error when responding to an incoming signal.

### SUMMARY

According to a first aspect, the present disclosure relates to a system for signal timing error correction. The system comprises: a receiver configured to receive a repetitive challenge signal from a device-under-test (DUT); and a signal generator. In response to the reception of the challenge signal, the receiver is configured to trigger the signal generator to generate a response signal; wherein the receiver is configured to receive the response signal. The system further comprises a controller configured to calculate a response time between the reception of the challenge signal and the reception of the response signal by the receiver; wherein the controller is configured to compare the calculated response time to a target response time; wherein the signal generator is further configured to generate a repetitive reply signal to the challenge signal and to forward the reply signal to the DUT; and wherein the signal generator is configured to apply a time offset to said reply signal based on the comparison of the calculated response time to the target response time.

This achieves the advantage that timing errors in the reply signal can be avoided. The comparison between the calculated and the target response time can indicate a trigger error of the system. By applying the time offset to the reply signal, this trigger error can be compensated.

The challenge signal, the response signal and the reply signal can each be RF (radio frequency) signals, such as radar signals. The challenge and reply signals are both repetitive signals, i.e., signals which comprise signal packets at a certain interval, while the response signal can comprise a single signal packet or pulse.

The response signal can be a calibration signal used for calibrating the system, i.e., for detecting and compensating the trigger error. This trigger error can comprise deterministic and random errors of the system. The deterministic errors could be known from the setup of the system and already be considered in the target response time. However, the random errors are typically unknown prior to performing the calibration measurement.

The reply signal can be an echo signal, e.g. a radar echo signal, which is generated in response to the challenge signal. The signal generator can transmit the reply signal back to the DUT.

The receiver can be or can comprise a signal and/or spectrum analyzer. The signal generator can be a vector signal generator.

The DUT can be a radar-under-test (RUT), e.g. an automotive radar sensor. The DUT could also be a user equipment.

In an implementation form of the first aspect, the controller is configured to calculate a time difference between the calculated response time and the target response time; wherein the controller is configured to determent the time offset based on said time difference.

For example, if the system is a radar target simulator, the target response time represents a certain distance between the DUT and the receiver and/or signal generator. The target response time can be an (ideal) reference time.

In an implementation form of the first aspect, the signal generator is configured to apply the time offset to a digitalized version of the reply signal; and/or the system comprises an adjustable delay unit for delaying the reply signal, wherein the signal generator adjusts the delay unit according to the time offset. For example, the adjustable delay unit delays an analog version of the reply signal, e.g., before it is transmitted to the DUT.

In an implementation form of the first aspect, the receiver and the signal generator are synchronized in terms of their baseband and/or frequency.

In an implementation form of the first aspect, the signal generator is configured to generate the reply signal to comprise repetitive signal packets, wherein the signal packets have the same repetition interval than the repetitive challenge signal.

For instance, the challenge signal also comprises repetitive signal packets, wherein the signal packets of the reply signal have the same repetition interval than the signal packets of the challenge signal.

In an implementation form of the first aspect, the signal generator is configured to generate the response signal asynchronous to the repetitive challenge signal and/or the reply signal packets. Hereby, asynchronous may refer to an “off-beat” generation of the response signal (i.e., off-beat to the signal packets of the challenge signal and/or reply signal).

In an implementation form of the first aspect, the receiver comprises a shared input channel configured for receiving the challenge signal and the response signal; wherein the system comprises a coupler which is connected between the DUT and the signal generator and configured to forward the challenge signal and the response signal to the shared input channel of the receiver.

In an implementation form of the first aspect, the receiver comprises a first input channel configured for receiving the challenge signal and a second input channel configured for receiving the response signal.

In an implementation form of the first aspect, the signal generator comprises a shared output channel configured to output the response signal and the reply signal, or the signal generator comprises a first output channel configured to output the response signal and a second output channel configured to output the reply signal.

In an implementation form of the first aspect, the receiver and the signal generator are communicatively connected to the DUT via a wired connection and/or via a wireless connection and/or via a coupler for exchanging the challenge signal and the reply signal.

In an implementation form, the system further comprises: a first cable connecting a first output of the signal generator to an input of the DUT, a second cable connecting an output of the DUT to the coupler, a third cable connecting the coupler to a second output of the signal generator, and a fourth cable connecting the coupler to the receiver; wherein, for calibrating the system, the first and the second cable are disconnected from the DUT and connecting with each other; wherein, while the first cable is connected to the second cable, the signal generator is configured to transmit a first calibration signal via its first output and a second calibration signal via its second output, wherein the first and the second calibration signal are transmitted by the signal generator with a known time offset; wherein the receiver is configured to receive the first and the second signal and to detect a further time offset between the receipt of the first and the second signal; and wherein the system is configured to perform a calibration based on the known time offset at transmission and the detected further time offset at receipt.

In this way, the system can be calibrated with regards to the length of the first, the second, the third and the fourth cable.

After receipt of the first and the second calibration signal with the receiver, the first and second cable can be re-connected to the DUT. During subsequent normal operation, the system can compensate for the cable lengths based on the calibration.

In an implementation form of the first aspect, the receiver and/or the signal generator comprise at least one attenuator and/or at least one power amplifier.

In an implementation form of the first aspect, the receiver is configured to analyze a repetition frequency of the challenge signal; and the signal generator is configured to generate the reply signal and/or apply the time offset to the reply signal based on said repetition frequency.

In an implementation form of the first aspect, the signal generator is configured to generate the reply signal based on a preprocessed signal and/or preprocessed signal components stored in a memory of the system.

In an implementation form of the first aspect, the signal generator is configured to adapt the reply signal according to a preconfigured scenario. For example, the scenario includes artificial or measured CIRs (channel impulse responses) and/or Micro-Doppler effects. If the DUT is an automotive radar sensor, the scenario could be a traffic scenario.

In an implementation form of the first aspect, the signal generator is configured to only forward the reply signal to the DUT after applying the time offset to the reply signal.

In an implementation form of the first aspect, the signal generator is configured to generate the response signal at a different frequency than the reply signal.

In an implementation form of the first aspect, the receiver and the signal generator are arranged in a shared housing.

According to a second aspect, the present disclosure relates to a method for signal timing error correction. The method comprises the steps of: receiving a repetitive challenge signal from a device-under-test, DUT, with a receiver; in response to the reception of the challenge signal, triggering a signal generator to generate a response signal; receiving the response signal with the receiver, calculating a response time between the reception of the challenge signal and the reception of the response signal by the receiver; comparing the calculated response time to a target response time; generating a repetitive reply signal to the challenge signal forwarding the reply signal to the DUT; and applying a time offset to said reply signal based on the comparison of the calculated response time to the target response time.

The method according to the second aspect of the present disclosure can be carried out by the system according to the first aspect of the present disclosure.

According to a third aspect, the present disclosure relates to a system for signal timing error correction. The system comprises: a receiver configured to receive a repetitive challenge signal from a device-under-test, DUT; and a signal generator; wherein, in response to the reception of the challenge signal, the receiver is configured to trigger the signal generator to generate a response signal; wherein the receiver is configured to receive the response signal. The system further comprises a controller configured to calculate a response time between the reception of the challenge signal and the reception of the response signal by the receiver; wherein the controller is configured to compare the calculated response time to a target response time; wherein the signal generator is configured to generate a reply signal to the challenge signal and to forward the repetitive reply signal to the DUT; and wherein the system comprises a communication interface configured to forward information derived from the comparison of the calculated response time to the target response time to the DUT.

For example, the DUT can analyze the reply signal and can determine a target distance based on the reply signal and the received information.

In an implementation form of the third aspect, the controller is configured to calculate a time difference between the calculated response time and the target response time; wherein the system is configured to forward the time difference to the DUT via the communication interface.

For example, the target response time represents a certain distance between the DUT and the receiver and/or signal generator. The target response time can be an (ideal) reference time.

In an implementation form of the third aspect, the receiver and the signal generator are synchronized in terms of their baseband and/or frequency.

In an implementation form of the third aspect, the signal generator is configured to generate the reply signal to comprise repetitive signal packets, wherein the signal packets have the same repetition interval than the repetitive challenge signal.

For instance, the challenge signal also comprises repetitive signal packets, wherein the signal packets of the reply signal have the same repetition interval than the signal packets of the challenge signal.

In an implementation form of the third aspect, the signal generator is configured to generate the response signal asynchronous to the repetitive challenge signal and/or the reply signal packets.

In an implementation form of the third aspect, the receiver comprises a shared input channel configured for receiving the challenge signal and the response signal; wherein the system comprises a coupler which is connected between the DUT and the signal generator and configured to forward the challenge signal and the response signal to the shared input channel of the receiver.

In an implementation form of the third aspect, the receiver comprises a first input channel configured for receiving the challenge signal and a second input channel configured for receiving the response signal.

In an implementation form of the third aspect, the signal generator comprises a shared output channel configured to output the response signal and the reply signal, or the signal generator comprises a first output channel configured to output the response signal and a second output channel configured to output the reply signal.

In an implementation form of the third aspect, the receiver and the signal generator are communicatively connected to the DUT via a wired connection and/or via a wireless connection and/or via a coupler for exchanging the challenge signal and the reply signal.

In an implementation form of the third aspect, the receiver and/or the signal generator comprise at least one attenuator and/or at least one power amplifier.

In an implementation form of the third aspect, the receiver is configured to analyze a repetition frequency of the challenge signal; and the signal generator is configured to generate the reply signal and/or apply the time offset to the reply signal based on said repetition frequency.

In an implementation form of the third aspect, the signal generator is configured to generate the reply signal based on a preprocessed signal and/or preprocessed signal components stored in a memory of the system.

In an implementation form of the third aspect, the signal generator is configured to adapt the reply signal according to a preconfigured scenario. For example, the scenario includes artificial or measured CIRs (channel impulse responses) and/or Micro-Doppler effects

In an implementation form of the third aspect, the signal generator is configured to generate the response signal at a different frequency than the reply signal.

In an implementation form of the third aspect, the receiver and the signal generator are arranged in a shared housing.

According to a fourth aspect, the present disclosure relates to a method for signal timing error correction. The method comprises the steps of: receiving a repetitive challenge signal from a device-under-test, DUT, with a receiver; in response to the reception of the challenge signal, triggering a signal generator to generate a response signal; receiving the response signal with the receiver, calculating a response time between the reception of the challenge signal and the reception of the response signal by the receiver; comparing the calculated response time to a target response time; generating a repetitive reply signal to the challenge signal and forwarding the reply signal to the DUT; and forwarding information derived from the comparison of the calculated response time to the target response time to the DUT.

The method according to the fourth aspect of the present disclosure can be carried out by the system according to the third aspect of the present disclosure.

### BRIEF DESCRIPTION OF THE DRAWINGS

Exemplary embodiments of the disclosure are now further explained with respect to the drawings by way of example only, and not for limitation. In the drawings:

FIG. 1A shows a schematic diagram of a system for signal timing error correction according to an embodiment.

FIG. 1B shows signals received and/or generated by the system of FIG. 1A according to an embodiment;

FIG. 2A shows a schematic diagram of a system for signal timing error correction according to an embodiment.

FIG. 2B shows signals received and/or generated by the system of FIG. 2A according to an embodiment;

FIG. 3 shows a schematic diagram of a system for signal timing error correction according to an embodiment;

FIG. 4 shows possible connections between a DUT and a system according to an embodiment;

FIG. 5 shows a schematic diagram of a system for signal timing error correction according to an embodiment;

FIG. 6 shows a schematic diagram of a system for signal timing error correction according to an embodiment;

FIG. 7 shows signals received and/or generated by the system of FIG. 6 according to an embodiment;

FIG. 8 shows a flow diagram of a method for signal timing error correction according to an embodiment;

FIG. 9 shows a schematic diagram of a system for signal timing error correction during a calibration according to an embodiment; and

FIGS. 10A to 10D show exemplary calibration signals of a system for signal timing error correction.

### DETAILED DESCRIPTIONS OF EMBODIMENTS

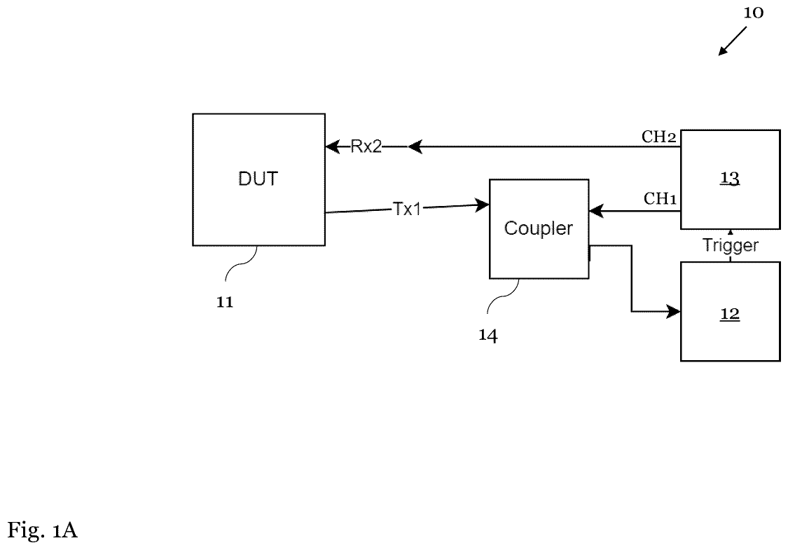

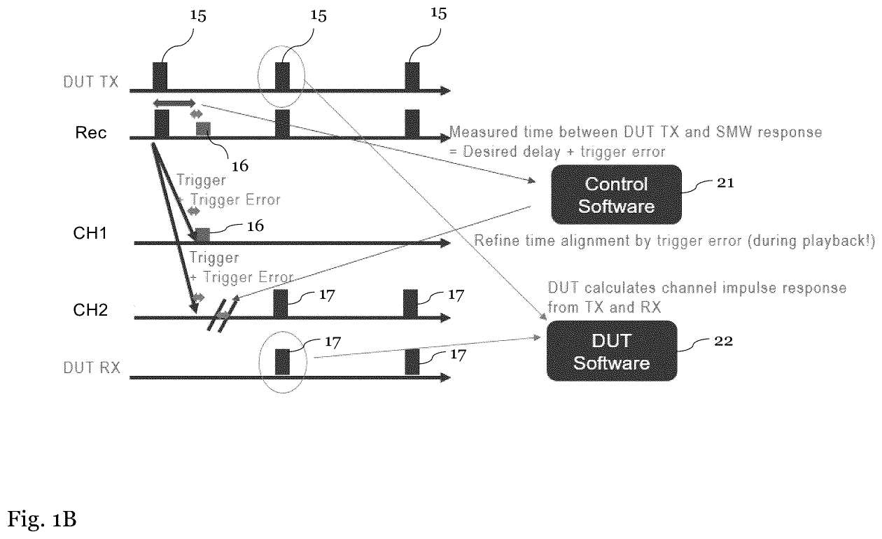

FIG. 1A shows a system 10 for signal timing error correction between a challenge signal received from a device-under-test (DUT) 11 and a reply signal according to an embodiment. The system 10 may be a radar target simulator or a component of a radar target simulator.

The system 10 comprises: a receiver 12 configured to receive a repetitive challenge signal from the DUT 11, and a signal generator 13, wherein, in response to the reception of the challenge signal, the receiver 12 is configured to trigger the signal generator 13 to generate a response signal. The receiver 12 is configured to receive the response signal. The system 10 further comprises a controller configured to calculate a response time between the reception of the challenge signal and the reception of the response signal by the receiver; wherein the controller is configured to compare the calculated response time to a target response time; wherein the signal generator 13 is configured to generate a repetitive reply signal to the challenge signal and to forward the reply signal to the DUT; and wherein the signal generator 13 is configured to apply a time offset to said reply signal based on the comparison of the calculated response time to the target response time.

The challenge signal, the response signal and/or the reply signal can be RF signals, in particular radar signals or more specifically UWB radar signals. However, these signals could also be other types of RF signals, such as WiFi or FMCW signals.

Both the challenge signal and the reply signal may comprise repetitive signal packets with the same repetition interval (see e.g. FIG. 1B). In particular, each signal packet of the reply signal (reply packet) may be a “reply” to a respective signal packet of the challenge signal.

For instance, the reply signal emulates an echo signal to the challenge signal, e.g. a radar echo signal. If the system 10 is a radar target simulator, it can simulated a certain target distance to the DUT 11 by adjusting a time difference between the signal packets of the challenge signal and the emission of corresponding reply signal packets. Thereby, also very short distances between the DUT 11 and a (simulated) target could be simulated by setting a very short time difference between a challenge signal packet and a corresponding response signal packet. For instance, the receiver 12 can analyze the periodicity of the challenge signal, such that a reply signal packet corresponding to a certain challenge signal packet can already be generated before the challenge signal packet is received.

The response signal can be a calibration signal used for calibrating the system, i.e., detecting and compensating a trigger error. The trigger error can comprise deterministic and random errors of the system 10. The deterministic errors could be known from the setup of the system and already be considered in the target response time. However, the random errors are typically unknown prior to performing the calibration measurement.

The response signal could correspond to one signal packet of the reply signal, which may be temporarily-shifted (off-beat) to the signal packets of the challenge and/or the reply signal. The signal packet of the response signal may therefore be referred to as “calibration packet”. The trigger error, in particular the random trigger error, of the response and the reply signal (i.e., of the calibration packet and of each reply packet) can be essentially identical. Thus, by determining the trigger error of the response signal, the same error is known for the reply signal packets and can thus be removed or reduced.

For example, for triggering the signal generator 13, the receiver 12 is configured to generate a trigger signal in response to the reception of the challenge signal. The signal generator can be configured to receive the trigger signal and to generate the response signal in response to the reception of the trigger signal. The trigger signal can be a control signal (e.g., also an RF signal).

The receiver 12 can comprise or can be a signal and/or spectrum analyzer. The signal/or spectrum analyzer or a control software thereof can calculate the response time and compare the calculated response time to the target response time.

The signal generator 13 could be a vector signal generator. The signal generator 13 can be configured to transmit the reply signal back to the DUT 11.

The signal generator 13 can comprises a first output channel CH1 configured to output the response signal and a second output channel CH2 configured to output the reply signal.

As shown in FIG. 1A, the system 10 can comprises a coupler 14 which configured to forward the challenge signal and the response signal to the shared input channel of the receiver 12. The coupler 14 can be a power splitter which is connected to the DUT 11, the signal generator 13 and the receiver 12.

FIG. 1B shows signals received and/or generated by the system of FIG. 1A according to an embodiment.

The first diagram (DUT Tx) shows the challenge signal 15 as emitted by the DUT 11. This challenge signal can comprise the repetitive signal packets (e.g., radar pulses) which are emitted by the DUT with a fixed period.

The second diagram (Rec) shows the signals received at the shared input of the receiver 12. This signals comprise the challenge signal 15 and the response signal 16.

The third diagram (CH1) shows the response signal 16 emitted by the first output channel CH1 of the signal generator 13, and the fourth diagram (CH2) shows the reply signal 17 emitted by the second output channel CH2 of the signal generator 13.

The fifth diagram shows the reply signal 17 as received by the respective DUT input Rx2 connected to CH2.

The signal generator 13 can generate and forward the response signal 16 in an asynchronous manner (i.e., off-beat) to the repetitive challenge and/or the reply signal 15, 17 packets. In this way, the signals can be efficiently separated by the receiver 12, as shown in the second diagram (Rec) of FIG. 1B. However, it is also possible that the calibration packets 16 and reply packets 17 overlap (response and challenge overlap).

In addition or alternatively, the signal generator 13 can be configured to generate the response signal 16 at a different frequency than the challenge signal 15 and/or the reply signal 17 (frequency stitching). This can also facilitate the separation of the signals by the receiver 12 and could be used when the receiver 12 has two input channels.

The controller can be configured to calculate a response time between the reception of the challenge signal 15 and the reception of the response signal 16 by the receiver 12, and to compare this response time to a target response time.

The calculated response time can be the sum of a desired delay (between the reception of the challenge signal 15 and the response signal 16) and the timing error of the reply signal. The target response time can correspond to the desired delay (without timing error). For instance, if the system 10 is a radar target simulator, the target response time can represent a certain distance to be simulated. The target response time can be an (ideal) reference time.

In an example, the controller calculates a time difference between the calculated response time and the target response time and determines the time offset based on said time difference. The time offset may correspond to the time difference or can be derived from the time difference. By applying the time offset to the reply signal, a trigger error of the system can be compensated.

The controller can execute a control software 21 to compare the calculated response time to the target response time and, in particular, to calculate the time difference.

For instance, the signal generator may be configured to only forward the reply signal to the DUT 11 after applying the time offset to the reply signal. For example, the system 10 only turns on a signal path from the signal generator 13 to the DUT 11 after the “calibration measurement” is performed (i.e., the trigger error is corrected).

Furthermore, the DUT 11 can be configured to compare the timing of the emitted challenge signal 15 and the reply signal 17, e.g. to determine a channel impulse response from Tx1 (output of the DUT) to Rx2 (input of the DUT). This calculation can be carried out by a software 22 of the DUT.

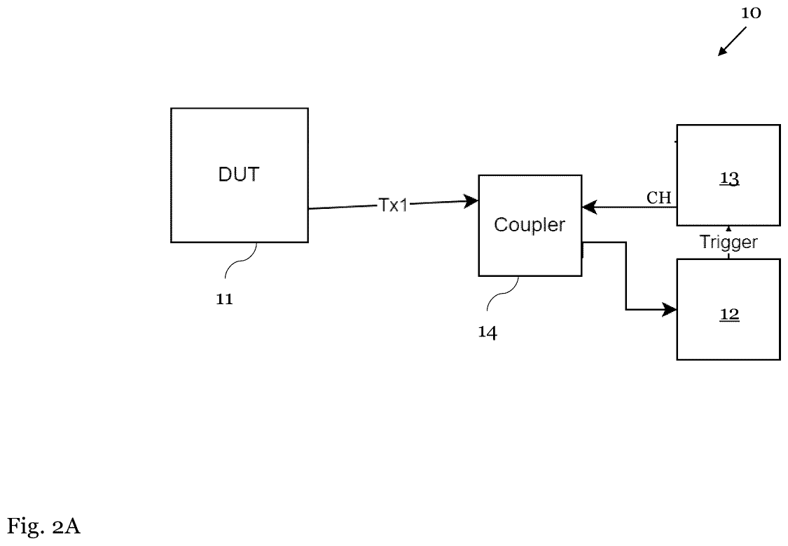

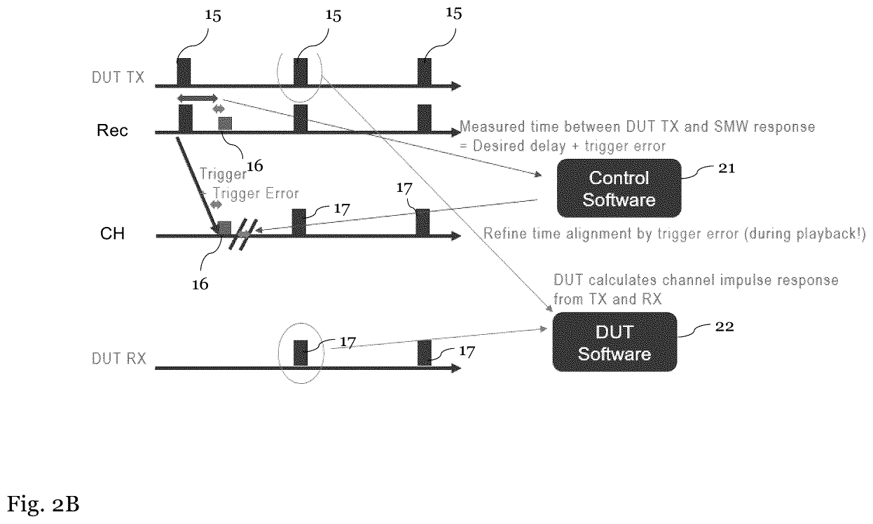

FIGS. 2A, 3, 4, 5 and 6 show exemplary embodiments of the system 10 or parts thereof, which build on the system 10 shown in FIG. 1A. Same elements are labelled with the same reference signs. Hereinafter, only the differences between FIG. 1A and FIGS. 2A to 6 are explained.

In the example shown in FIG. 2A, the signal generator 13 comprises a shared output channel CH configured to output both the response signal and the reply signal to the receiver 12 respectively the DUT 11. For instance, both signals 16, 17 could be played in a synchronous manner via the shared channel CH. A shared input channel of the receiver 12 can be connected to the shared output channel of the signal generator 13. The DUT 11 could receive both the response and the reply signal, but could ignore the response (i.e., calibration) signal.

FIG. 2B shows exemplary signals received and/or generated by the system of FIG. 2A. Due to the signal generator only comprising one output channel CH, both the response signal 16 and the reply signal 17 are transmitted via said channel CH (third diagram from the top in FIG. 2A).

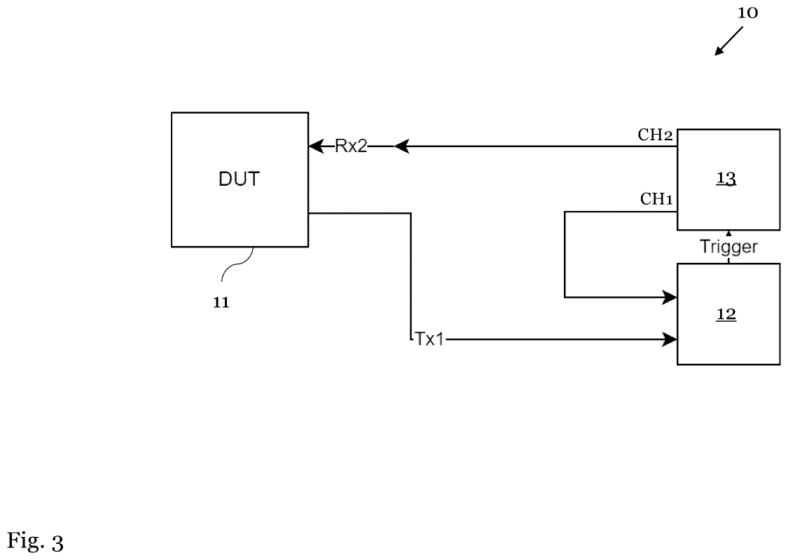

FIG. 3 shows a further exemplary embodiment of the system 10, wherein the receiver comprises two input channels and the signal generator comprises two output channels CH1, CH2. For instance, one output channel of the signal generator 13 is directly connected to one input channel of the receiver 12 to forward the response signal, wherein the further input channel of the receiver 12 receives the challenge signal and the further output channel of the signal generator 13 forwards the reply signal to the DUT 11.

In summary, the system 10 may comprise the following combinations of signal generator 13, receiver 12 and coupler 14:
a one-channel signal generator, a coupler and a one-channel receiver;
a two-channel signal generator, a coupler and a one-channel receiver; or a two-channel signal generator and a two-channel receiver.

For example, the receiver 12 and the signal generator 13 can be arranged in a shared housing. The coupler 14 can be integrated in the housing or can be an external component connected to the housing.

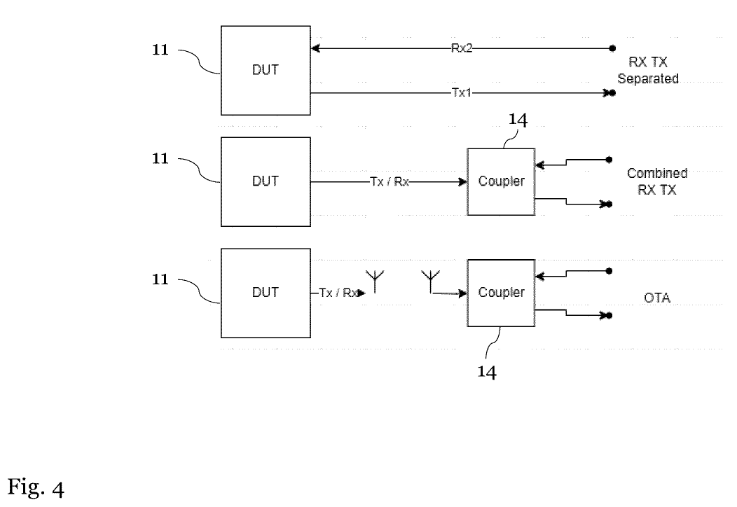

FIG. 4 shows three possible connections between the DUT 11 and the system 10. Via these connections the DUT 11 and the system 10 can exchange the challenge and the reply signals.

In the upper illustration of FIG. 4, the DUT 11 comprises separate input Rx2 and output Tx1 ports, wherein each port is connected to the system 10 via a respective signal line. Depending on the number of input and output channels of the receiver 12 and signal generator 13, the system may comprise a number of couplers (e.g., splitters), for instance two couplers 14 in case both the receiver 12 the signal generator 13 have two channels.

In the middle illustration of FIG. 4, the DUT 11 comprises a single Rx/Tx port, which is connected to a coupler 41, which connects the DUT port with either an input or an output channel of the system 10.

In the lower illustration of FIG. 4, the DUT 11 comprises a single Rx/Tx port and the connection between the DUT and the system 10 is at least partially wireless, e.g. using two antennas 42 for exchanging signals.

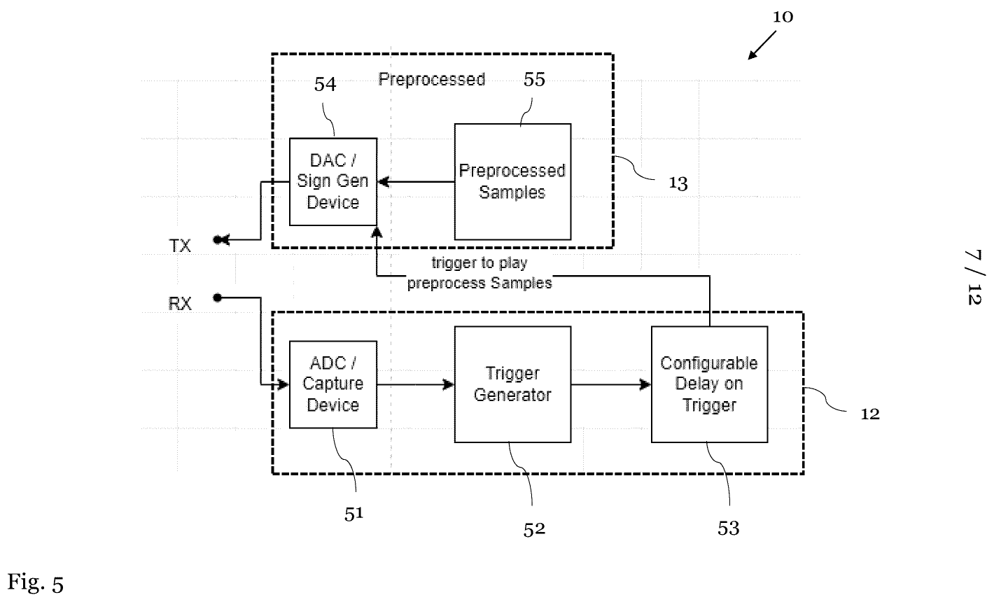

FIG. 5 shows a further exemplary embodiment of the system 10.

The receiver 12 may comprise a capture unit 51 for capturing the response signal and/or the reply signal. The capture unit 51 can comprise an analog-to-digital converter (ADC) for digitalizing a captured signal.

The receiver 12 may further comprise a trigger generator 52 for generating the trigger signal and a further unit 53 configured to apply a configurable delay on the trigger signal. Via this delay, the forwarding of the trigger signal to the signal generator 13 and, thus, the transmission of the response and/or reply signals can be delayed for a certain amount of time. If the system 10 is, e.g., a radar target simulator, the target distance can be adjusted via this delay. This delay may correspond to the target response time or can be considered when selecting the target response time.

The units 52 and 53 could be components of the controller.

The signal generator 13 can comprise a signal generation unit 54 for generating and transmitting the response and reply signals. The signal generation unit 54 can comprise a digital-to-analog converter (DAC) for converting a digital response/reply signal to an analog signal, which is forwarded to the DUT 11 and/or the receiver 12.

The signal generator 13 can be configured to apply the time offset to a digitalized version of the reply signal, i.e., prior to the converting the reply signal to an analog signal via the DAC 54. This time offset can be applied as a digital impairment (IQ delay) to a reply signal that is currently played by the signal generator 13, such that the signal generator 13 “jumps” within the signal to correct for the measured trigger error.

Alternatively, the system 10 may comprise an adjustable delay unit for delaying the reply signal, wherein the signal generator adjusts the delay unit according to the time offset. For example, the adjustable delay unit delays an analog version of the reply signal, e.g., before it is transmitted to the DUT. The delay unit could be arranged in the signal path of the reply signal downstream of the unit 54 in FIG. 5, e.g. at an output of the signal generator 13.

The signal generator 13 can further comprise a memory 55 configured for storing preprocessed signals or sample components (samples). For instance, the signal generator 13 can be configured to generate the reply signal and/or the response signal based on these preprocessed signals and/or signal components.

The signal generator 13 can further be configured to adapt the reply signal and/or the response signal according to a preconfigured scenario. For instance, the signal generator 13 can receive information on the captured challenge signal from the receiver 12 (e.g., form an analyzer of the receiver), and can further receive input from a user, an API and/or a database. Based on this information, the signal generator 13 can select a “scenario” which may comprise artificial or measured CIR (channel impulse responses) and/or Micro-Doppler signal components. The signal generator 13 can apply signal processing to the reply signal in order to account for the scenario, and then play back an adapted waveform with the scenario to the DUT 11. The adaption of the reply signal according to the scenario can be done online (by the signal generator 13) or offline (by another computing device connected to the signal generator 13).

The receiver 12 and/or the signal generator 13 may further comprise at least one attenuator and/or at least one power amplifier. These elements can be arranged at different points of a signal chain to increase an SNR (signal to noise ratio) and/or a balance leveling of TX and RX signals (i.e., of the reply/response signal and the challenge signal).

The system 10 can further analyze the repetition frequency of challenge packets (i.e., the signal packets of the challenge signal) and use this repetition frequency to control a trigger and/or playback delay of the response and/or reply signal. For example, the receiver 12 is configured to analyze a repetition frequency of the challenge signal, and the signal generator 13 is configured to generate the reply signal and/or to apply the time offset to the reply signal based on said repetition frequency.

For example, the receiver 12 and the signal generator 12 are synchronized in terms of their baseband and/or frequency. Due to this synchronization, their baseband signal processing may operate in a coordinated manner, e.g. in terms of timing, frequency and/or or phase.

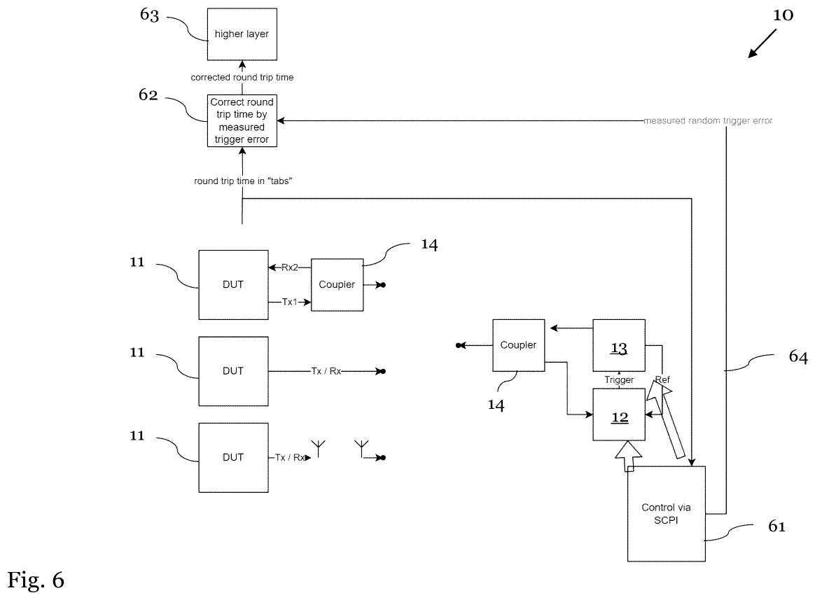

FIG. 6 shows a schematic diagram of the system 10 according to an embodiment. Thereby, the three possible connection scenarios between DUT 11 and system 10, which were already shown in FIG. 4, are illustrated.

FIG. 6 illustrates the controller 61 of the system, which is e.g. based on the SCPI (Standard Commands for Programmable Instrument) protocol. The controller 61 can be or can comprise a processor.

The system 10 as shown in FIG. 6 may comprise a communication interface 64 which is configured to forward information derived from the comparison of the calculated response time to the target response time to the DUT 11. In this way, the timing error, e.g. the trigger error, in the reply signal which can be derived from the comparison may be corrected by the DUT 11, in particular by a processing unit 62 of the DUT 11 (or connected to the DUT 11).

The communication interface 64 could be a wired or wireless interface. For instance, the interface is a USB, a WiFi, a Bluetooth, or an NFC interface.

For instance, the DUT 11 may calculate the time difference between the challenge signal and the reply signal. If the DUT 11 is a radar, this difference may correspond to a distance reading. Based on the forwarded information from the system 10, the processing unit 62 of the DUT 11 can adapt respectively correct this time difference to remove or at least reduce the effect of the trigger error. This could be done in a post-processing step by the DUT 11 or a connected device. The thus corrected result could then be reported to a higher layer 63 and/or displayed by the DUT 11.

The information, which is forwarded via the interface 64, may be the time difference between the calculated response time and the target response time. If the information is forwarded to the DUT 11, the system 10 might not apply the time offset to the reply signal. Instead the trigger error could be corrected by the DUT 11 in this case.

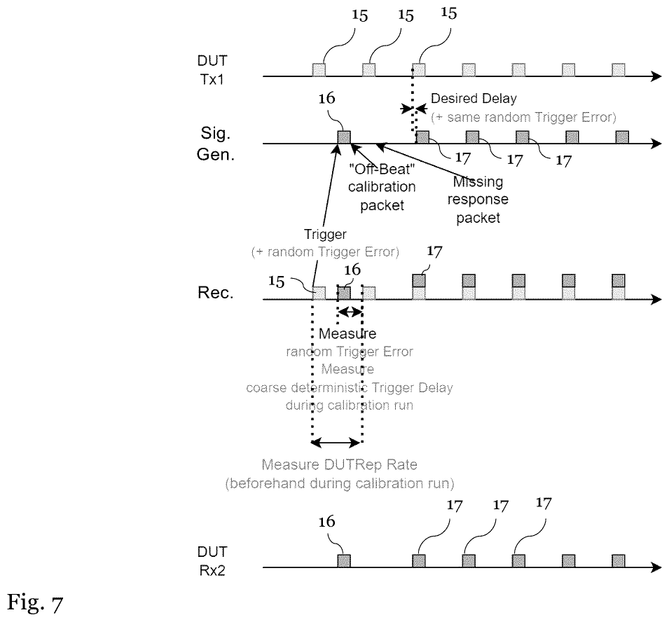

FIG. 7 shows signals received and/or generated by the system 10 of FIG. 6 according to an embodiment.

As shown in FIG. 7, the system 10 can be configured to first perform a calibration measurement with the response signal 16 (“off-beat” calibration signal), and subsequently to forwards the reply signal to the DUT. The “correction” of the reply signal (e.g., removal of the trigger error by applying the time offset) can be done by the signal generator 13 of the system 10 or by the DUT 11 based on forwarded information on the trigger error.

The response signal 16 could also be received by the DUT 11 as implied by the lower diagram of FIG. 7. Further, the receiver 12 can receive both the response and the reply signal as indicated by the third diagram from the top in FIG. 7.

The system 10 as shown in any one of FIG. 1A, 2A, 3, 4, 5 or 6 can be an UWB radar target simulator. In UWB radar applications, trigger accuracy of the receiver/analyzer which receives the packet and the signal generator which plays back a reply is especially challenging. Even with aligned basebands of the receiver/analyzer 12 and the signal generator 13, a trigger jitter due to the noise of the edge of the signal may lead to a poor performance of the overall system. By measuring the trigger delay by means of capturing the challenge signal and a response packet (calibration packet) in one capture buffer (i.e. relate them in time with high precision, ~ps . . . ), and then correcting the reply signal played to the DUT 11 and/or correct the result of the DUT 11 or on a higher layer, the effect of this trigger jitter can be minimized.

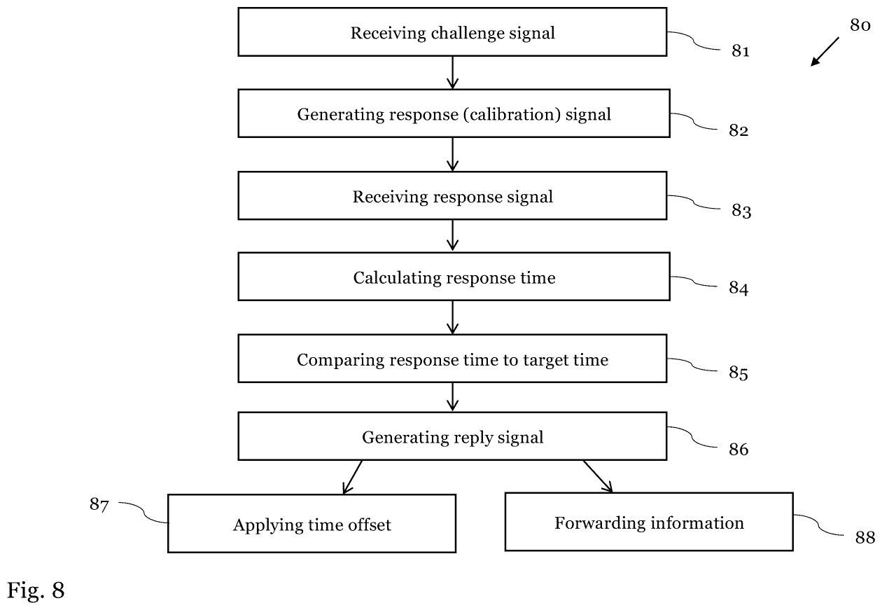

FIG. 8 shows a flow diagram of a method 80 for signal timing error correction according to an embodiment.

The method 80 comprises the steps of: receiving 81 a repetitive challenge signal from a DUT with a receiver; in response to the reception 81 of the challenge signal, triggering 82 a signal generator to generate a response signal; receiving 83 the response signal with the receiver, calculating 84 a response time between the reception of the challenge signal and the reception of the response signal by the receiver; comparing 85 the calculated response time to a target response time; and generating 86 a repetitive reply signal to the challenge signal and forwarding the reply signal to the DUT.

Furthermore, the method 80 may comprise applying 87 a time offset to said reply signal based on the comparison 85 of the calculated response time to the target response time.

In addition or alternatively, to the application 87 of the time offset, the method 80 may comprise the step of forwarding 88 information derived from the comparison of the calculated response time to the target response time to the DUT.

In summary, the method responds to an older packet of the respective challenge signal from the DUT and may thereby consider the time interval between the repetitive challenges. The method also addresses issues which could arise from a lack of trigger accuracy of the receiver/analyzer 12 which receives the packets and triggers the signal generator 13 to play back the response signal.

A further task that may be performed with the system 10 is an absolute distance calibration in order to cancel the influence of cable lengths during a measurement with the DUT 11. Therefore, a calibration plane is defined at the port of the DUT 11, wherein this calibration plane is calibrated using only equipment already present in the system 10. For instance, a user may require a “reflection” after 1 m and the DUT receives a response after exactly: 1 m*2*3 ns/m=6 ns.

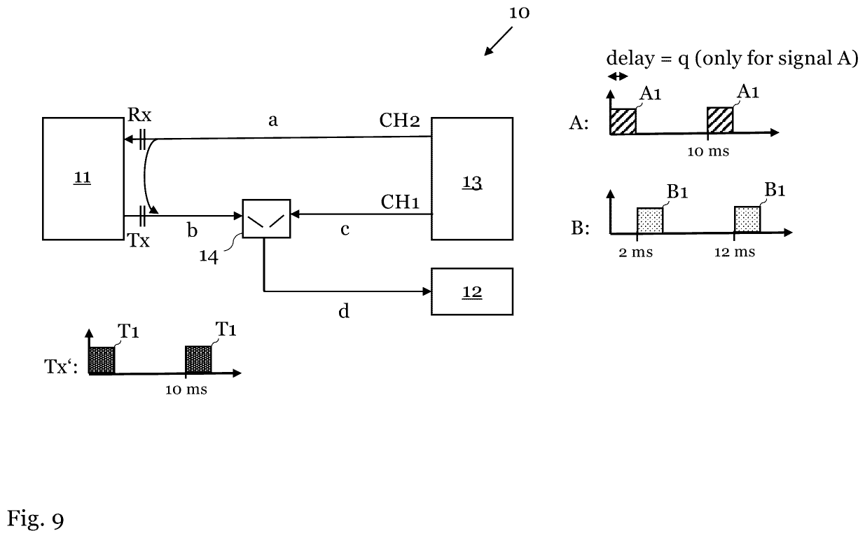

This calibration is visualized in FIG. 9, which shows a further exemplary embodiment of the system 10 and the DUT 11. In the system 10, the cables connecting the DUT 11 and the system components 12, 13, 14 with each other respectively the time delays caused by said cables are indicated by reference signs a, b, c and d.

In a first step of a calibration procedure, the cables a, b connected to the input respectively output Rx and Tx of the DUT 11 are disconnected from the DUT 11 and directly connected to each other as indicated by the curved arrow in FIG. 9. Then, two synchronous signals A and B are output on the two output channels CH2 and CH1 of the signal generator 13, wherein the signal A played on channel CH2 has a constant delay q.

The signals A and B are exemplarily visualized in FIG. 9. Thereby, the signal packets in both signals A and B have a periodicity of 10 ms, wherein the packets of A and B have an offset of 2 ms to each other.

The lengths of the cable paths from the signal generator 13 to the DUT 11 and then from the DUT 11 back to the receiver 12 can be calibrated based on the following considerations:

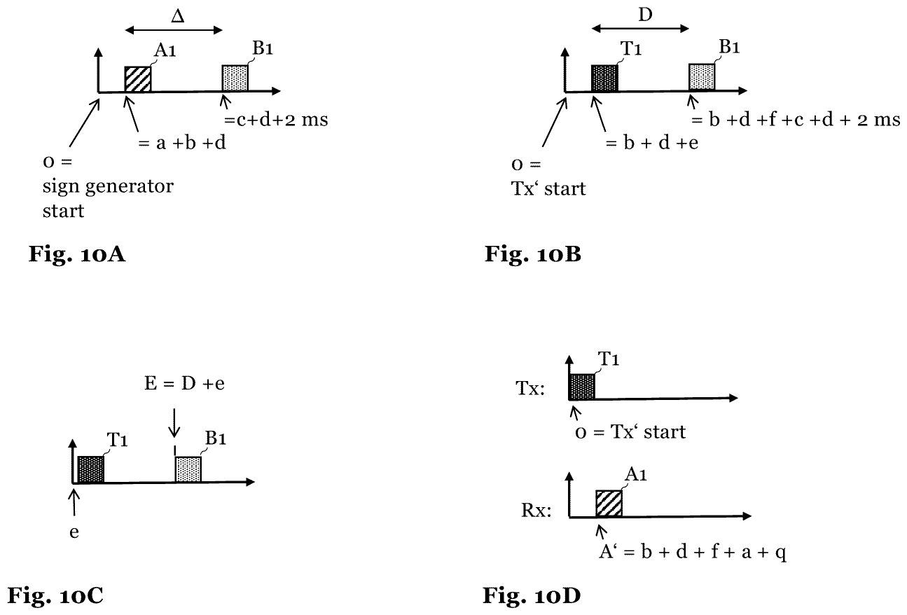

If the signal generator 13 transmits signals A and B simultaneously, and assuming q is zero, the time delay between the receipt of the two signal packets of A and B at the receiver 12 is A, as exemplarily visualized in FIG. 10A.

Due to the cables, the signal packet A1 of signal A is received with an offset to the “start time” (i.e., time of transmission) of a+b+d, and the signal packet B1 of signal B is received with an offset of c+d+2 ms, the 2 ms being the exemplary offset between signals A and B as shown in FIG. 9. Thus, the delay A can be written as:

$$Δ = c + d + 2 ms - ( a + b + d )$$

$$Δ = 2 ms + c - a - b$$

Hence, the delay A is stable with no trigger delay.

In a second step of the calibration procedure, the cables a, b are connected back to the DUT 11, i.e., the DUT input Rx is connected to signal generator 13 and the DUT output Tx is connected to the receiver 12 via the coupler 14.

With the thus re-connected DUT, the signal A is sent via CH2 to the DUT input Rx. In response, the DUT transmits signal Tx′ via the DUT output Tx. The signal Tx′ is forwarded via cable b, splitter 14 and cable d to the input of the receiver 12. Tx′ comprises signal packets with periodicity of 10 ms, as indicated in FIG. 9. The receipt of Tx′ triggers the generation and transmission of a further signal B from the signal generator via CH1. The further signal B is forwarded via cable c, coupler 14 and cable d to the input of the receiver 12.

FIG. 10B shows the delay D between the receipt of a signal packet T1 of signal Tx′ and a response signal packet B1 of signal B at the receiver 12, wherein the zero point is the Tx′ starting time, i.e., the time at which Tx′ was output by the DUT.

Due to the cables, the signal packet T1 of signal Tx′ is received with an offset of b+d+e, wherein e is a trigger delay, namely the “burst to capture” trigger delay. The signal packet B1 of signal B is received with an offset of b+d+f+c+d+2 ms, wherein f is a further trigger delay, namely the “burst to play at signal generator” trigger delay.

The delay D can be written as:

$$D = b + d + f + c + d - ( b + d + e ) + 2 ms$$

$$D = f + c + d - e + 2 ms$$

FIG. 10C shows the time-dependence of the receipt of the two signal components Tx′ and B1, wherein the zero point of the chart is the arrival of T1 at the receiver. Thereby, e is the delay between arrival and registered receipt. The receipt of B1 can be written as E=D+e, which can be re-written to:

$$E = f + c + d + 2 ms$$

FIG. 10D indicates the transmission of a signal packet of T1 of Tx′ from the DUT output Tx and the subsequent receipt of a signal packet A1 from the signal generator at the DUT input Rx. In both cases, the zero-point is chosen to be the Tx′ starting time. As indicated, A1 is received at the DUT with an offset of: A′=b+d+f+a+q.

Based on the relationships between the various parameters determined above, a formula for calculating the constant delay q can be developed:

$$E - Δ = D - Δ + e = f + c + d - e + 2 ms - ( 2 ms + c - a - b ) + e$$

$$= f + d + a + b$$

$$= b + d + f + a$$

$$= {A}^{′} - q$$

$$⇒ q = {A}^{′} - ( D - Δ + e ) = {A}^{′} - ( E - Δ )$$

Alternatively to this calibration routine, a user could also disconnect all cables and use a VNA to measure the individual cable lengths. However, this would have the drawback of additional errors due to the various connecting and disconnecting steps. Further, a VNA would be needed instead of using the already existing hardware of the setup

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired and advantageous for any given or particular application.

1. A system for signal timing error correction, comprising:
a receiver configured to receive a repetitive challenge signal from a device-under-test, DUT; and
a signal generator;
wherein, in response to the reception of the challenge signal, the receiver is configured to trigger the signal generator to generate a response signal;
wherein the receiver is configured to receive the response signal;
wherein the system further comprises a controller configured to calculate a response time between the reception of the challenge signal and the reception of the response signal by the receiver;
wherein the controller is configured to compare the calculated response time to a target response time;
wherein the signal generator is further configured to generate a repetitive reply signal to the challenge signal and to forward the reply signal to the DUT; and
wherein the signal generator is configured to apply a time offset to said reply signal based on the comparison of the calculated response time to the target response time.

2. The system of claim 1,
wherein the controller is configured to calculate a time difference between the calculated response time and the target response time;
wherein the controller is configured to determent the time offset based on said time difference.

3. The system of claim 1,
wherein the signal generator is configured to apply the time offset to a digitalized version of the reply signal; and/or
wherein the system comprises an adjustable delay unit for delaying the reply signal, wherein the signal generator is configured to adjusts the delay unit according to the time offset.

4. The system of claim 1,
wherein the receiver and the signal generator are synchronized in terms of their baseband and/or frequency.

5. The system of claim 1,
wherein the signal generator is configured to generate the reply signal to comprise repetitive signal packets, wherein the signal packets have the same repetition interval than the repetitive challenge signal.

6. The system of claim 5,
wherein the signal generator is configured to generate the response signal asynchronous to the repetitive challenge signal and/or the reply signal packets.

7. The system of claim 1,
wherein the receiver comprises a shared input channel configured for receiving the challenge signal and the response signal;
wherein the system comprises a coupler which is connected between the DUT and the signal generator and configured to forward the challenge signal and the response signal to the shared input channel of the receiver.

8. The system of claim 1,
wherein the receiver comprises a first input channel configured for receiving the challenge signal and a second input channel configured for receiving the response signal.

9. The system of claim 1,
wherein the signal generator comprises a shared output channel configured to output the response signal and the reply signal, or
wherein the signal generator comprises a first output channel configured to output the response signal and a second output channel configured to output the reply signal.

10. The system of claim 1,
wherein the receiver and the signal generator are communicatively connected to the DUT via a wired connection and/or via a wireless connection and/or via a coupler for exchanging the challenge signal and the reply signal.

11. The system of claim 10, further comprising:
a first cable connecting a first output of the signal generator to an input of the DUT, a second cable connecting an output of the DUT to the coupler,
a third cable connecting the coupler to a second output of the signal generator, and
a fourth cable connecting the coupler to the receiver;
wherein, for calibrating the system, the first and the second cable are disconnected from the DUT and connecting with each other;
wherein, while the first cable is connected to the second cable, the signal generator is configured to transmit a first calibration signal via its first output and a second calibration signal via its second output, wherein the first and the second calibration signal are transmitted by the signal generator with a known time offset;
wherein the receiver is configured to receive the first and the second signal and to detect a further time offset between the receipt of the first and the second signal;
wherein the system is configured to perform a calibration based on the known time offset at transmission and the detected further time offset at receipt.

12. The system of claim 1,
wherein the receiver and/or the signal generator comprise at least one attenuator and/or at least one power amplifier.

13. The system of claim 1,
wherein the receiver is configured to analyze a repetition frequency of the challenge signal;
wherein the signal generator is configured to generate the reply signal and/or apply the time offset to the reply signal based on said repetition frequency.

14. The system of claim 1,
wherein the signal generator is configured to generate the reply signal based on a preprocessed signal and/or preprocessed signal components stored in a memory of the system.

15. The system of claim 1,
wherein the signal generator is configured to adapt the reply signal according to a preconfigured scenario.

16. The system of claim 1,
wherein the signal generator is configured to only forward the reply signal to the DUT after applying the time offset to the reply signal.

17. The system of claim 1,
wherein the signal generator is configured to generate the response signal at a different frequency than the reply signal.

18. The system of claim 1,
wherein the receiver and the signal generator are arranged in a shared housing.

19. A method for signal timing error correction, comprising:
receiving a repetitive challenge signal from a device-under-test, DUT, with a receiver;
in response to the reception of the challenge signal, triggering a signal generator to generate a response signal;
receiving the response signal with the receiver,
calculating a response time between the reception of the challenge signal and the reception of the response signal by the receiver;
comparing the calculated response time to a target response time;
generating a repetitive reply signal to the challenge signal and forwarding the reply signal to the DUT; and
applying a time offset to said reply signal based on the comparison of the calculated response time to the target response time.

20. A system for signal timing error correction, comprising:
a receiver configured to receive a repetitive challenge signal from a device-under-test, DUT; and
a signal generator;
wherein, in response to the reception of the challenge signal, the receiver is configured to trigger the signal generator to generate a response signal;
wherein the receiver is configured to receive the response signal;
wherein the system further comprises a controller configured to calculate a response time between the reception of the challenge signal and the reception of the response signal by the receiver;
wherein the controller is configured to compare the calculated response time to a target response time;
wherein the signal generator is configured to generate a repetitive reply signal to the challenge signal and to forward the reply signal to the DUT; and
wherein the system comprises a communication interface configured to forward information derived from the comparison of the calculated response time to the target response time to the DUT.
